(19) United States
(12) Patent Application Publication
(10) Pub. No.: US 2008/0169121 A1
(43) Pub. Date: Jul. 17, 2008

(54) Printed wiring board unit for method of detecting rising level of electrically-conductive body in bore

(75) Inventor: Mitsuo Suehiro, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/000,335

(22) Filed: Dec. 11, 2007

(30) Foreign Application Priority Data
Jan. 11, 2007 (JP) 2007-003529

(51) Int. Cl. H05K 1/03; H01L 21/00; G01R 27/00

(52) U.S. Cl. 174/255; 29/25.01; 324/600

(57) ABSTRACT

A through bore penetrates through a substrate. The through bore defines a space surrounded by an insulating wall surface. A lead terminal of an electronic component is received in the through bore. An electrically-conductive body is placed in the through bore to extend to an exposed portion at the surface of the substrate. An auxiliary electrically-conductive body is exposed in the space of the through bore for connection to the electrically-conductive body. The auxiliary electrically-conductive body extends to an exposed portion at the surface of the substrate. The lead terminal contacts with an electrically-conductive body in the through bore. Electrical conduction is detected between the lead terminal and the auxiliary electrically-conductive body for detecting the rising level of the electrically-conductive body. When such electric conduction is detected, the electrically-conductive body is supposed to reach the level of the auxiliary electrically-conductive body.

### BACKGROUND OF THE INVENTION

1. Field of the Invention

The present invention relates to a printed wiring board unit including a substrate and an insert mounting device (IMD) mounted on the surface of the substrate.

2. Description of the Prior Art

A lead terminal of a connector is received in a plated through hole formed in a printed wiring board from the front surface of the printed wiring board in a method of making the printed wiring board unit, for example. The plated through hole penetrates through the printed wiring board between the front surface and the back surface of the printed wiring board. The back surface of the printed wiring board is immersed in a solder bath. A melted solder in the solder bath rises into the plated through hole from the back surface of the printed wiring board. When the printed wiring board is taken out of the solder bath, the solder in the printed wiring board is cured or hardened. Electric connection is thus established between the lead terminal and the plated through hole.

When the solder does not sufficiently rise into the plated through hole from the back surface of the printed wiring board, electric connection cannot be established between the lead terminal and the plated through hole. X rays are utilized to examine the inner structure of the printed wiring board in order to observe the rising level of the solder in the plated through hole, for example. However, the shadows of the lead terminal in the plated through hole and the electrically-conductive pattern in the printed wiring board come over the shadow of the solder. It is thus impossible to detect the rising level of the solder with accuracy.

### SUMMARY OF THE INVENTION

It is accordingly an object of the present invention to provide a printed wiring board and a printed wiring board unit, enabling an accurate detection of the rising level of an electrically-conductive body.

According to a first aspect of the present invention, there is provided a printed wiring board unit comprising: a substrate including insulating layers; a through bore penetrating through the substrate between a first surface and a second surface opposite the first surface, the through bore defining a space surrounded by an insulating wall surface; an electronic component placed on the first surface of the substrate, the electronic component having a lead terminal placed in the through bore; an electrically-conductive body placed in the through bore to extend to an exposed portion at least one of the first and second surfaces, the electrically-conductive body contacting with the lead terminal of the electronic component; and an auxiliary electrically-conductive body exposed in the space of the through bore at a position between adjacent ones of the insulating layers for connection to the electrically-conductive body, the auxiliary electrically-conductive body extending to an exposed portion at least one of the first and second surfaces.

The through bore defines the space surrounded by the insulating wall surface. The lead terminal of the electronic component is received in the through bore. The lead terminal contacts with the electrically-conductive body in the through bore. The electrically-conductive body is exposed at least one of the first and second surfaces of the substrate. The auxiliary electrically-conductive body is exposed in the space of the through bore at a position between the adjacent ones of the insulating layers. The auxiliary electrically-conductive body is exposed at least one of the first and second surfaces of the substrate. It is detected whether or not electrical conduction is established between the lead terminal and the auxiliary electrically-conductive body for detecting the rising level of the electrically-conductive body. When such electric conduction is detected, it is detected that the electrically-conductive body has risen up to the level of the auxiliary electrically-conductive body. The rising level of the electrically-conductive body is reliably detected in this manner.

The auxiliary electrically-conductive body in the printed wiring board unit may comprise: an electrically-conductive pattern placed on the surface of one of the insulating layers; and an electrically-conductive material placed in a bore extending from at least one of the first and second surfaces to the surface of the insulating layer, the electrically-conductive material extending from the first surface to the surface of-the insulating layer. The printed wiring board unit can be incorporated in an electronic apparatus, for example.

According to a second aspect of the present invention, there is provided a printed wiring board comprising: a substrate including insulating layers; a through bore penetrating through the substrate between a first surface and a second surface opposite the first surface, the through bore defining a space surrounded by an insulating wall surface; and an auxiliary electrically-conductive body exposed in the space of the through bore at a position between adjacent ones of the insulating layers, the auxiliary electrically-conductive body extending to an exposed portion at the first surface. The printed wiring board of this type greatly contributes to establishment of the aforementioned printed wiring board unit.

The auxiliary electrically-conductive body in the printed wiring board may comprise: an electrically-conductive pattern disposed on the surface of one of the insulating layers; and an electrically-conductive material placed in a bore extending from the first surface to the surface of the insulating layer, the electrically-conductive material extending from the first surface to the surface of the insulating layer.

According to a third aspect of the present invention, there is provided a method of making a printed wiring board, comprising: forming a substrate including insulating layers; and forming a through bore penetrating through the substrate from a first surface of the substrate to a second surface opposite the first surface to define a space surrounded by an insulating wall surface, the through bore allowing exposure of an auxiliary electrically-conductive body in the space at a position between adjacent ones of the insulating layers, the auxiliary electrically-conductive body extending to an exposed portion at the first surface. This method allows the production of the aforementioned printed wiring board.

According to a fourth aspect of the present invention, there is provided a method of detecting the rising level of an electrically-conductive body, comprising: connecting a first contact to an electrically-conductive material placed in a through bore penetrating through a substrate including insulating layers from a first surface of the substrate to a second surface opposite the first surface, the electrically-conductive body exposed at least one of the first and second surfaces, the through bore receiving a lead terminal of an electronic component mounted on the first surface; connecting a second contact to an auxiliary electrically-conductive body exposed in a space defined in the through bore at a position between adjacent ones of the insulating layers, the electrically-conductive body extending to an exposed portion at least one of the first and second surfaces; and measuring electric resistance between the first and second contacts.

The method enables connection of the first contact to the electrically-conductive body placed in the through bore. The second contact is connected to the auxiliary electrically-conductive body exposed on at least one of the first and second surfaces of the substrate. The auxiliary electrically-conductive body is exposed in the space of the through bore at a position between adjacent ones of the insulating layers. Electric resistance is measured between the first and second contacts. When the measured resistance is lower than a predetermined resistance, for example, electric conduction is detected between the electrically-conductive body in the through bore and the auxiliary electrically-conductive body. It is detected that the electrically-conductive body has risen up to the level of the auxiliary electrically-conductive body. The rising level of the electrically-conductive body is reliably detected in this manner.

### BRIEF DESCRIPTION OF THE DRAWINGS

The above and other objects, features and advantages of the present invention will become apparent from the following description of the preferred embodiments in conjunction with the accompanying drawings, wherein:

FIG. 1 is a perspective view schematically illustrating a server computer as a specific example of an electronic apparatus of the present invention;

FIG. 2 is a perspective view schematically illustrating a main board unit as a specific example of a printed wiring board unit according to the present invention;

FIG. 3 is an enlarged partial sectional view taken along the line 3-3 in FIG. 2;

FIG. 4 is an enlarged partial plan view schematically illustrating the surface of a printed wiring board;

FIG. 5 is an enlarged partial sectional view taken along the line 5-5 in FIG. 4;

FIG. 6 is an enlarged partial sectional view taken along the line 6-6 in FIG. 4;

FIG. 7 is an enlarged partial sectional view taken along the line 7-7 in FIG. 3;

FIG. 8 is an enlarged partial sectional view taken along the line 8-8 in FIG. 3;

FIG. 9 is an enlarged partial sectional view taken along the line 9-9 in FIG. 5;

FIG. 10 is an enlarged partial sectional view taken along the line 10-10 in FIG. 6;

FIG. 11 is an enlarged partial sectional view schematically illustrating the process of making a resin substrate;

FIG. 12 is an enlarged partial sectional view schematically illustrating the process of forming through bores in the resin substrate;

FIG. 13 is an enlarged partial sectional view schematically illustrating the resin substrate subjected to a plating process;

FIG. 14 is an enlarged partial sectional view schematically illustrating the front and back surfaces of the resin substrate subjected to an etching process;

FIG. 15 is an enlarged partial sectional view schematically illustrating solder rising into through holes and through bores;

FIG. 16 is an enlarged partial sectional view schematically illustrating measurement of electric resistance; and

FIG. 17 is an enlarged partial sectional view, corresponding to FIG. 3, schematically illustrating a printed wiring board unit according to another specific example of the present invention.

### DESCRIPTION OF THE PREFERRED EMBODIMENTS

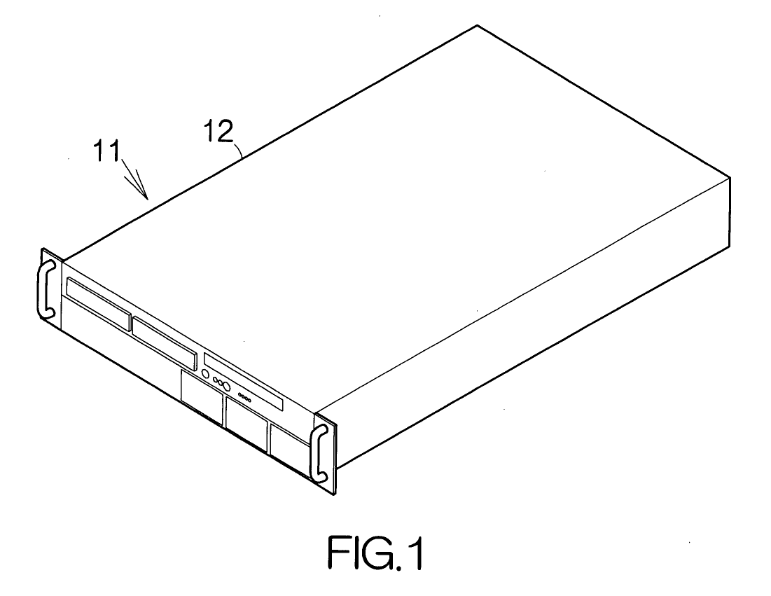

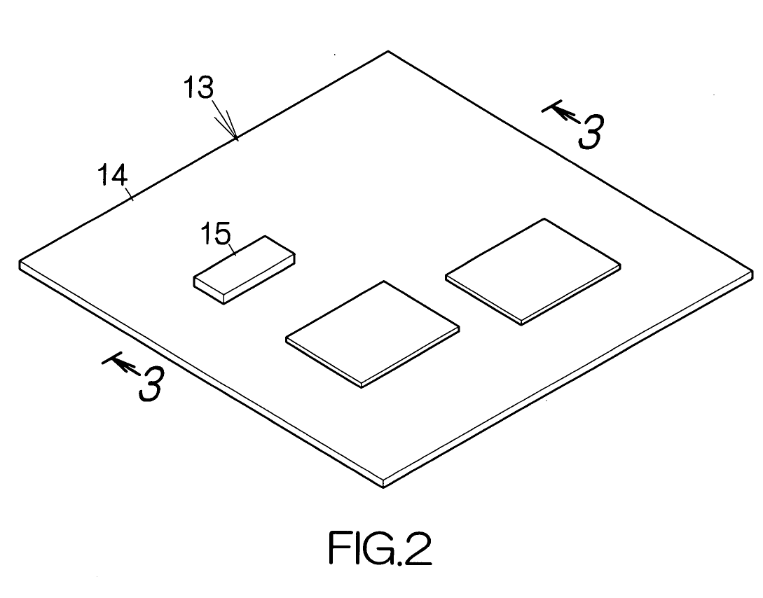

FIG. 1 schematically illustrates a server computer 11 as a specific example of an electronic apparatus according to an embodiment of the present invention. The server computer 11 is mounted on a rack, for example. The server computer 11 includes an enclosure 12. A printed circuit board unit or main board unit is enclosed in the enclosure 12. As shown in FIG. 2, the main board unit 13 includes a printed wiring board 14. An electronic component 15 is mounted on the printed wiring board 14. The electronic component 15 includes a connector, for example. The electronic component 15 is a so-called insert mounting device (IMD).

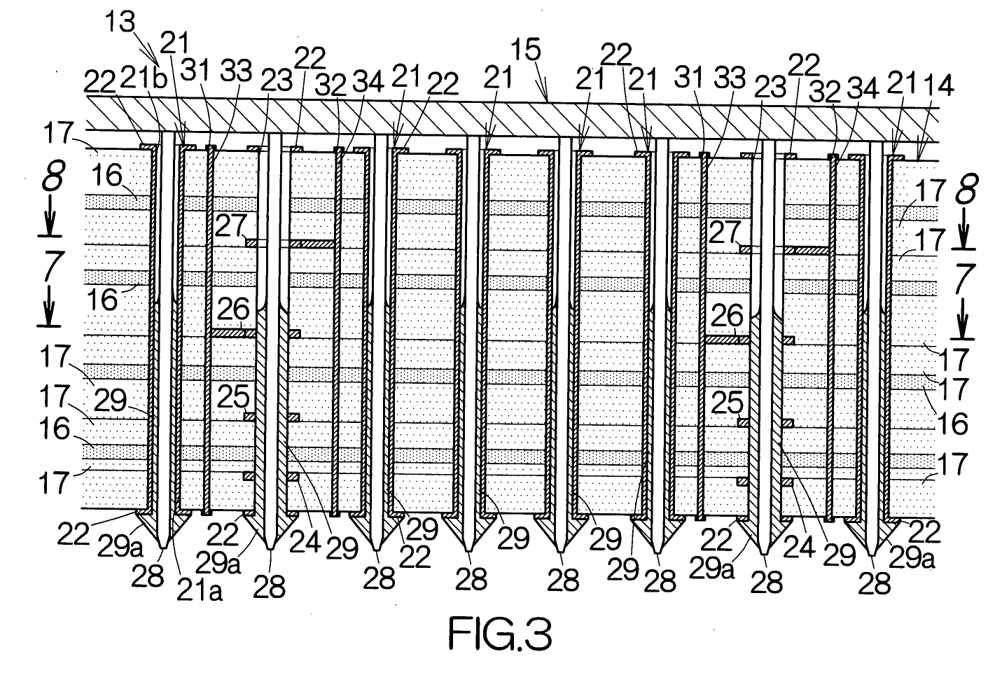

As shown in FIG. 3, the printed wiring board 14 has a layered structure including core resin layers 16 and insulating layers 17 formed on the front and back surfaces of the individual core resin layers 16. The core resin layers 16 and the insulating layers 17 correspond to an insulating layer according to the present invention. The core resin layer 16 and the insulating layer 17 are made of a resin material containing glass fiber cloth, for example. An epoxy resin is employed as the resin material, for example. The individual core resin layer 16 exhibits a sufficient rigidity to maintain its shape by itself.

Plated through holes 21 are formed in the printed wiring board 14. The individual plated through hole 21 includes a through bore 21a penetrating between the front and back surfaces of the printed wiring board 14 and a cylindrical metallic wall 21b formed on the inner surface of the through bore 21a. The metallic wall 21b is connected to land patterns 22 on the front and back surfaces of the printed wiring board 14. The metallic wall 21b and the land patterns 22 are made of an electrically-conductive material such as copper, for example. The front surface of the printed wiring board 14 corresponds to one of the first and second surfaces while the back surface of the printed wiring board 14 corresponds to the other one of the first and second surfaces.

Through bores, namely non-plated through holes 23, are formed in the printed wiring board 14. The non-plated through holes 23 penetrate through the printed wiring board 14 between the front and back surfaces of the printed wiring board 14. The non-plated through holes 23 are designed to extend in parallel with the plated through holes 21. The individual non-plated through hole 23 defines a cylindrical space, for example. The cylindrical space is surrounded by the insulating material of the core resin layers 16 and the insulating layers 17. The aforementioned land patterns 22 are formed on the front and back surfaces of the printed wiring board 14 around the openings of the non-plated through holes 23.

Electrically-conductive patterns, namely first to fourth land patterns 24, 25, 26, 27, are exposed in the cylindrical space. The first to fourth land patterns 24, 25, 26, 27 are placed between adjacent ones of the insulating layers 17. The first to fourth land patterns 24, 25, 26, 27 are made of an electrically-conductive material such as copper. The first to fourth land patterns 24, 25, 26, 27 are placed at levels corresponding to 10%, 25%, 50% and 75%, for example, of the thickness of the printed wiring board 14, from the back surface of the printed wiring board 14, respectively.

The plated through holes 21 and the non-plated through holes 23 each receive a lead terminal 28 of the electronic component 15 inside. The tip ends of the lead terminals 28 protrude from the back surface of the printed wiring board 14. An electrically-conductive body, namely solder 29, is filled in the plated through holes 21 and the non-plated through holes 23. The solder 29 forms a fillet 29a on the back surface of the printed wiring board 14. The solder 29 allows an electronic connection of the lead terminals 28 to the plated through holes 21, the land patterns 22 and the first to fourth land patterns 24, 25, 26, 27.

First and second bores 31, 32 are formed in the printed wiring board 14. The first and second bores 31, 32 are designed to extend in parallel with the non-plated through hole 23. The first and second bores 31, 32 penetrate through the printed wiring board 14 between the front and back surfaces of the printed wiring board 14. First electrically-conductive material 33 is filled in the first bore 31. Second electrically-conductive material 34 is filled in the second bore 32. The first and second electrically-conductive materials 33, 34 extend between the front surface and the back surface of the printed wiring board 14. The first and second electrically-conductive materials 33, 34 are made of an electrically-conductive material such as copper, for example. The first electrically-conductive material 33 is connected to the third land pattern 26. The second electrically-conductive material 34 is connected to the fourth land pattern 27.

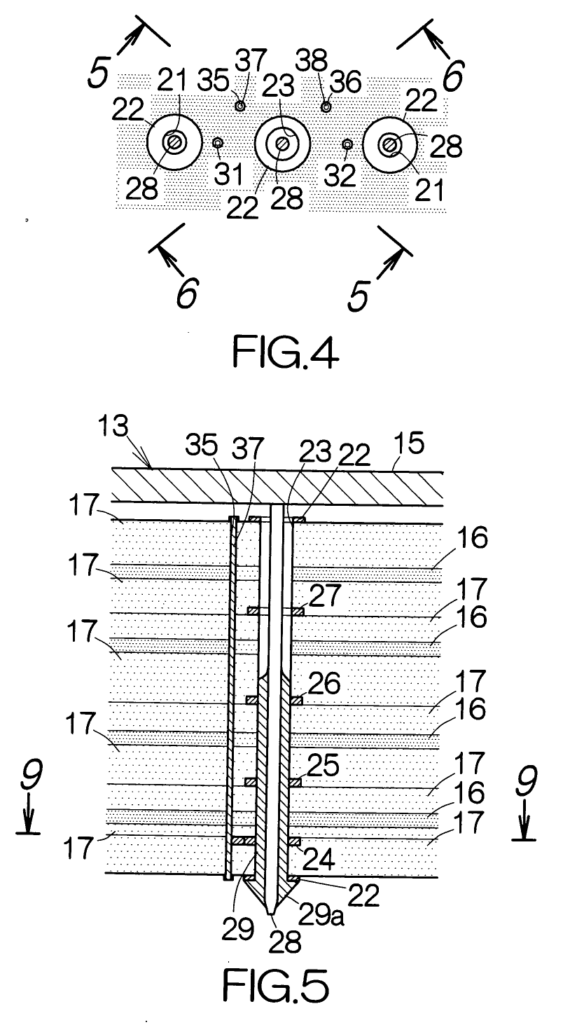

As shown in FIG. 4, third and fourth bores 35, 36 are formed in the printed wiring board 14. The third and fourth bores 35, 36 are designed to extend in parallel with the non-plated through hole 23 and the first and second bores 31, 32. The first, second, third and fourth bores 31, 32, 33, 34 are located at positions. around the non-plated through hole 23. Third electrically-conductive material 37 is filled in the third bore 35. Fourth electrically-conductive material 38 is filled in the fourth bore 36. The third and fourth electrically-conductive materials 37, 38 are made of an electrically-conductive material such as copper, for example.

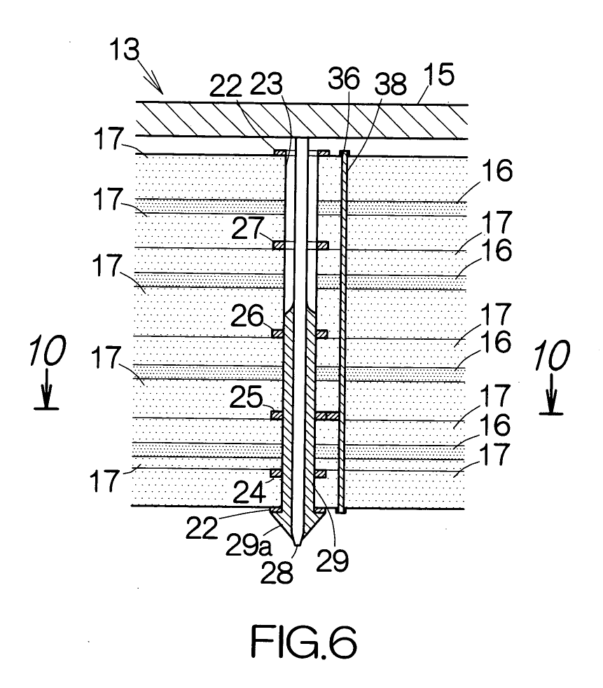

As shown in FIG. 5, the third bore 35 penetrates through the printed wiring board 14 between the front and back surfaces of the printed wiring board 14. The third electrically-conductive material 37 extends from the front surface to the back surface of the printed wiring board 14. The third electrically-conductive material 37 is connected to the first land pattern 24. As shown in FIG. 6, the fourth bore 36 penetrates through the printed wiring board 14 between the front and back surfaces of the printed wiring board 14. The fourth electrically-conductive material 38 extends from the front surface to the back surface of the printed wiring board 14. The fourth electrically-conductive material 38 is connected to the second land pattern 25.

Here, the combination of the third land pattern 26, the first bore 31 and the first electrically-conductive material 33 correspond to an auxiliary electrically-conductive body according to the present invention. Likewise, the combination of the fourth land pattern 27, the second bore 32 and the second electrically-conductive material 34 correspond to an auxiliary electrically-conductive body according to the present invention. The combination of the first land pattern 24, the third bore 35 and the third electrically-conductive material 37 correspond to an auxiliary electrically-conductive body according to the present invention. The second land pattern 25, the fourth bore 36 and the fourth electrically-conductive material 38 correspond to an auxiliary electrically-conductive body.

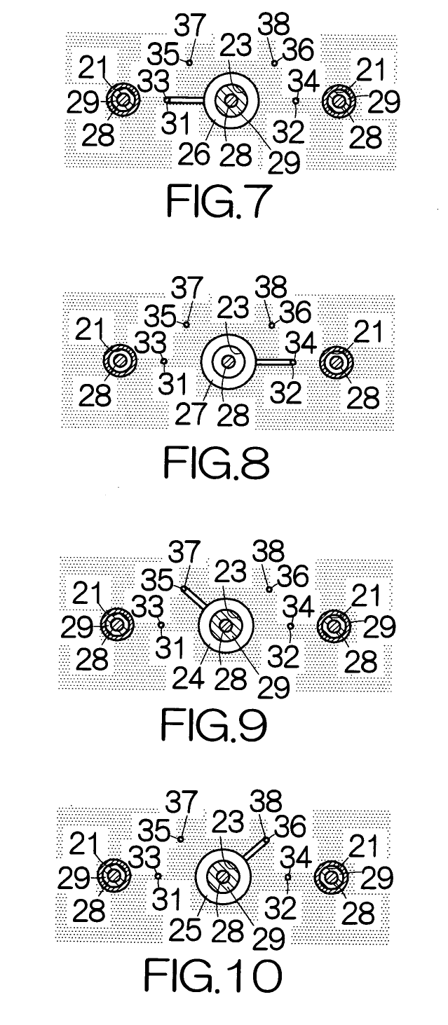

As shown in FIG. 7, the third land pattern 26 serves to connect the non-plated through hole 23 to the first bore 31 along the surface of the insulating layer 17. As shown in FIG. 8, the fourth land pattern 27 serves to connect the non-plated through hole 23 to the second bore 32 along the surface of the insulating layer 17. As shown in FIG. 9, the first land pattern 24 serves to connect the non-plated through hole 23 to the third bore 35 along the surface of the insulating layer 17. As shown in FIG. 10, the second land pattern 25 serves to connect the non-plated through hole 23 to the fourth bore 36 along the surface of the insulating layer 17.

When electric resistance is measured on the back surface of the printed wiring board 14 based on the lead terminal 28 and the first electrically-conductive material 33 in the main board unit 13, for example, it is possible to detect whether or not electric conduction is established through the solder 29, the first land patterns 24 and the first electrically-conductive material 33, as described later. The detection of the electric conduction demonstrates the solder 29 reaching the level of the first land pattern 24. The first to fourth land patterns 24, 25, 26, 27 are placed at the levels, from the back surface, equal to 10%, 25%, 50% and 75%, for example, of the thickness of the printed wiring board 14, respectively. The rising level of the solder 29 in the non-plated through hole 23, or the plated through hole 21, can thus be reliably detected based on detection whether or not electric conduction is established between the lead terminal 28 and each of the second electrically-conductive material 34, the third electrically-conductive material 37 and the fourth electrically-conductive material 38.

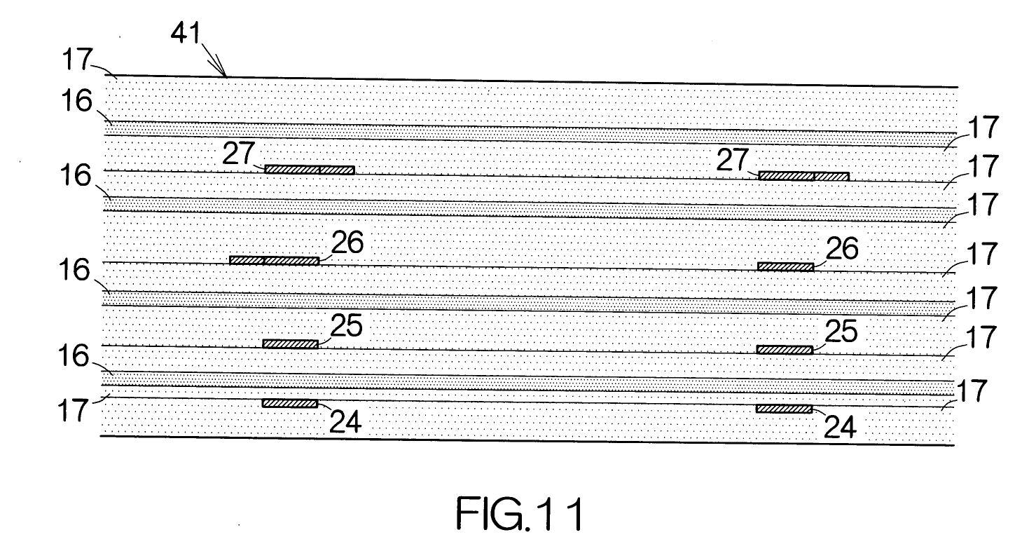

Next, a brief description will be made on a method of making the main board unit 13. The printed wiring board 14 is first made. Prepregs, not shown, are laminated on the front and back surfaces of the core resin layers 16. The first to fourth land patterns 24, 25, 26, 27 are formed on the surfaces of the prepregs, respectively. As shown in FIG. 11, a resin substrate 41 is made in this manner. The first to fourth land patterns 24, 25, 26, 27 are placed between adjacent ones of the insulating layers 17.

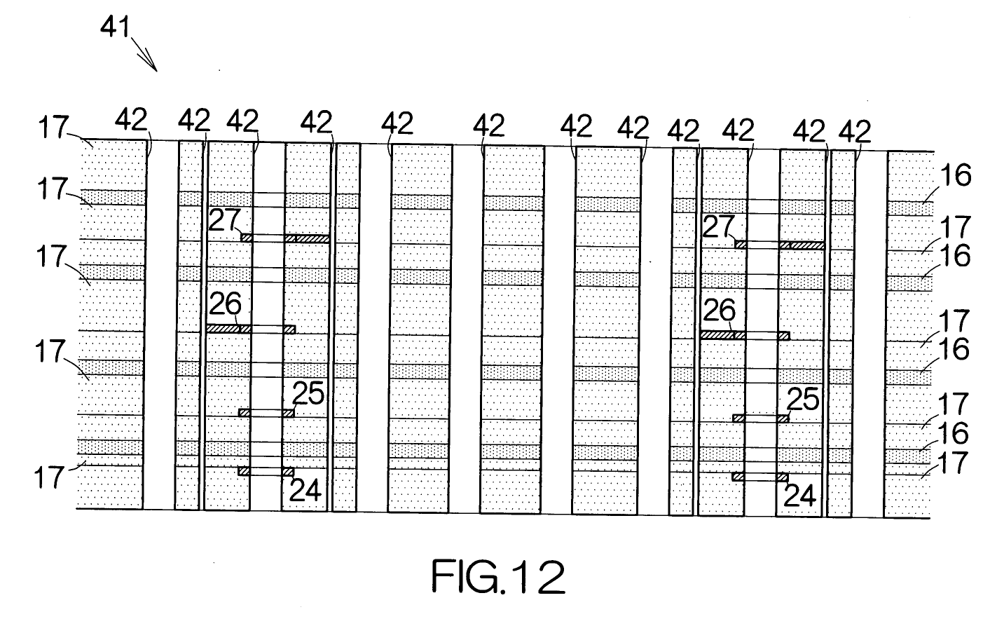

As shown in FIG. 12, through bores 42 are formed in the resin substrate 41. The through bores 42 correspond to the through bores 21a, the non-plated through holes 23, the first bores 31, the second bores 32, the third bores 35, and the fourth bores 42. A drill may be utilized to form the through bores 42, for example. The first to fourth land patterns 24, 25, 26, 27 are respectively exposed in the cylindrical spaces of the through bores 42 corresponding to the non-plated through holes 23.

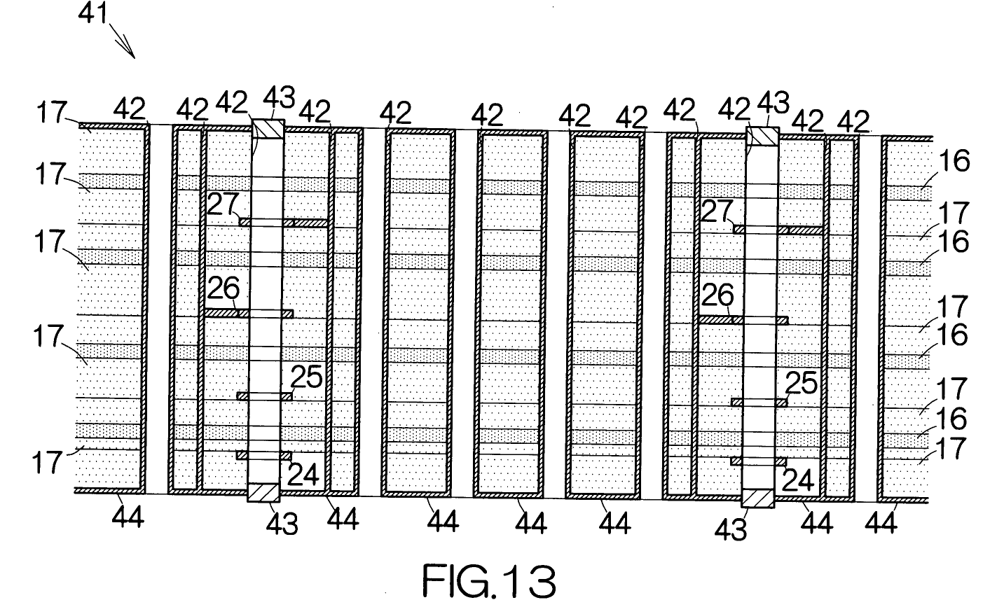

The resin substrate 41 is then subjected to a plating process. Copper is utilized for the plating process. As shown in FIG. 13, a resist material 43 is fitted in the opening of each of the through bores 42 corresponding to the non-plated through holes 23 prior to the plating process. A copper film 44 is formed over the front and back surfaces 41 and inner surfaces of the through bores 42. The resist materials 43 prevent formation of the copper film 44 over the inner surfaces of the through bores 42 corresponding to the non-plated through holes 23.

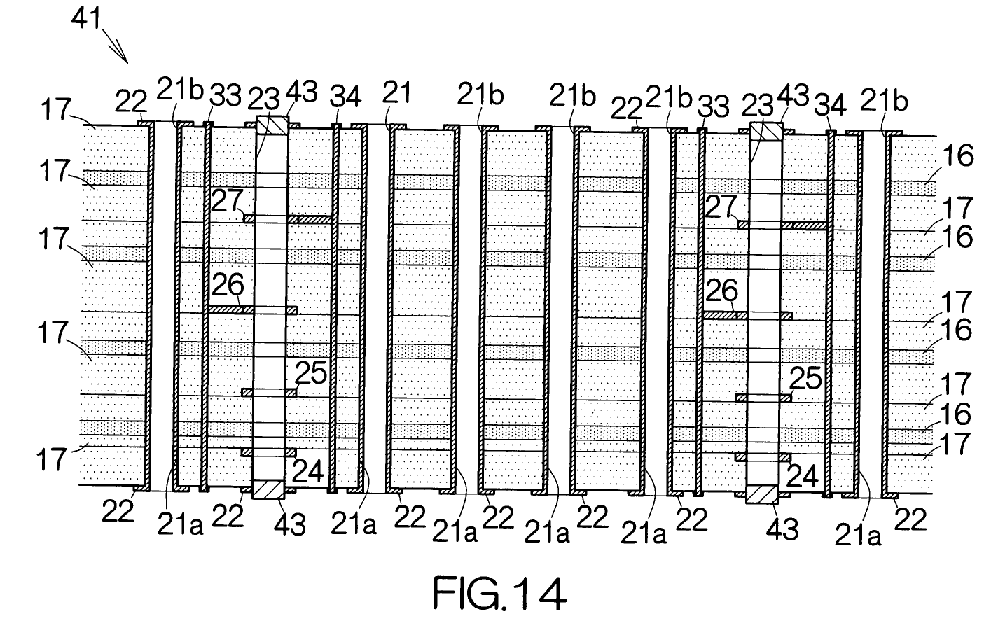

An etching process is then applied to the copper film 44 on the front and back surfaces of the resin substrate 41. A resist material, not shown, is formed on the surface of the copper film 44 in a predetermined pattern for the etching process. As shown in FIG. 14, the land patterns 22 are formed on the front and back surfaces of the resin substrate 41. The plated through holes 21 are isolated from each other. The resist materials 43 are then removed. The printed wiring board 14 is produced in this manner.

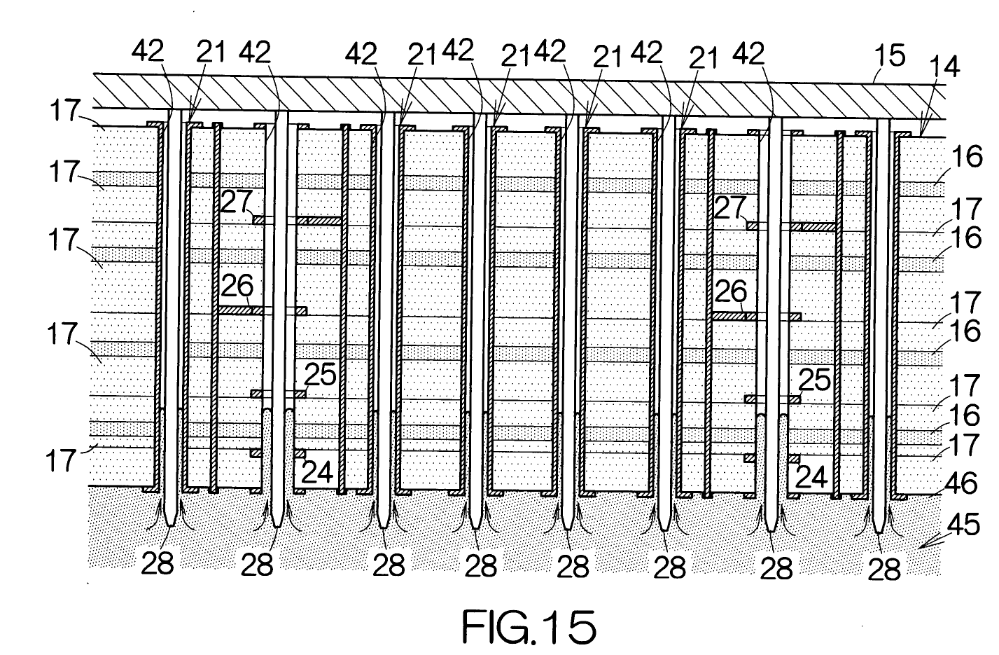

The lead terminals 28 of the electronic component 15 are inserted into the through bores 42. As shown in FIG. 15, the back surface of the printed wiring board 14 is immersed in a melted solder 46 in a solder bath 45. The melted solder 46 rises into the through bores 42 from the back surface of the printed wiring board 14 based on capillarity. The printed wiring board 14 is taken out of the solder bath 45 after immersed for a predetermined duration of time. The melted solder 46 is cooled, so that the melted solder 46 gets cured or hardened. The main board unit 13 is produced in this manner.

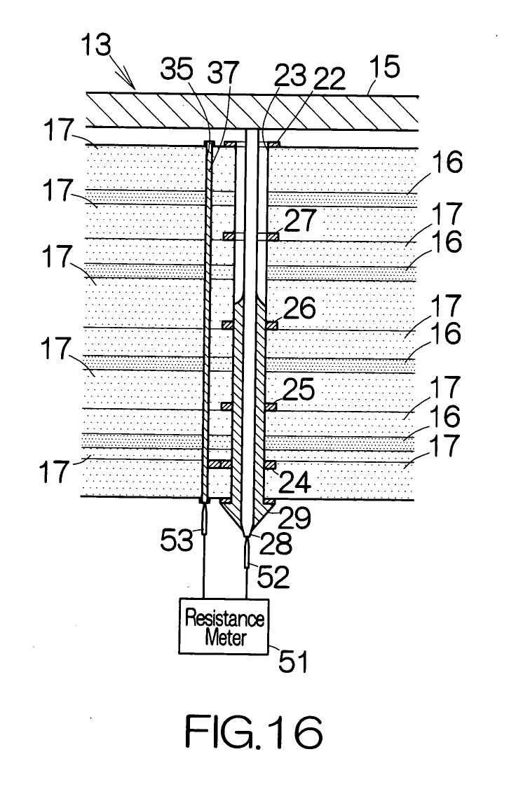

A brief description will be made on a method of detecting the rising level of the solder. As shown in FIG. 16, a resistance meter 51 is prepared for detecting the rising level of the solder. A first contact 52 of the resistance meter 51 is connected to the lead terminal 28. A second contact 53 of the resistance meter 51 is likewise connected to the third electrically-conductive material 37 of the third bore 35. Electric resistance is measured between the first and second contacts 52, 53.

When the measured resistance is lower than a predetermined resistance, electric conduction is detected through the solder 29, the first land pattern 24 and the third electrically-conductive material 37. Connection is confirmed between the solder 29 and the first land pattern 24. This demonstrates that the solder 29 has risen up to the level of the first land pattern 24. The value of the predetermined resistance may be determined based on an experimental observation, for example.

Simultaneously, it is detected whether or not so-called cracks and voids are formed in the solder 29 between the back surface of the printed wiring board 14 and the first land pattern 24. When cracks and voids are formed in the solder 29, for example, the contact area between the lead terminal 28 and the solder 29 is reduced, for example. A path for electric current is narrowed. Cracks and voids thus cause an increase in the electric resistance. Accordingly, the measured resistance lower than the predetermined resistance demonstrates that no cracks or voids are formed in the solder 29.

The second contact 53 of the resistance meter 51 is connected to the fourth electrically-conductive material 38, the first electrically-conductive material 33 and the second electrically-conductive material 34 in sequence. Electric resistance is measured for each of the connections. It is detected whether or not the solder 29 has risen up to the level of the second, the third or the fourth land pattern 25, 26, 27 in this manner. Simultaneously, it is detected whether or not cracks and voids are formed. The rising level of the solder 29 in the non-plated through hole 23 is reliably observed. The rising level of the solder 29 in the non-plated through hole 23 reflects that of the solder 29 in the plated through hole 21. The rising level of the solder 29 is reliably detected in this manner.

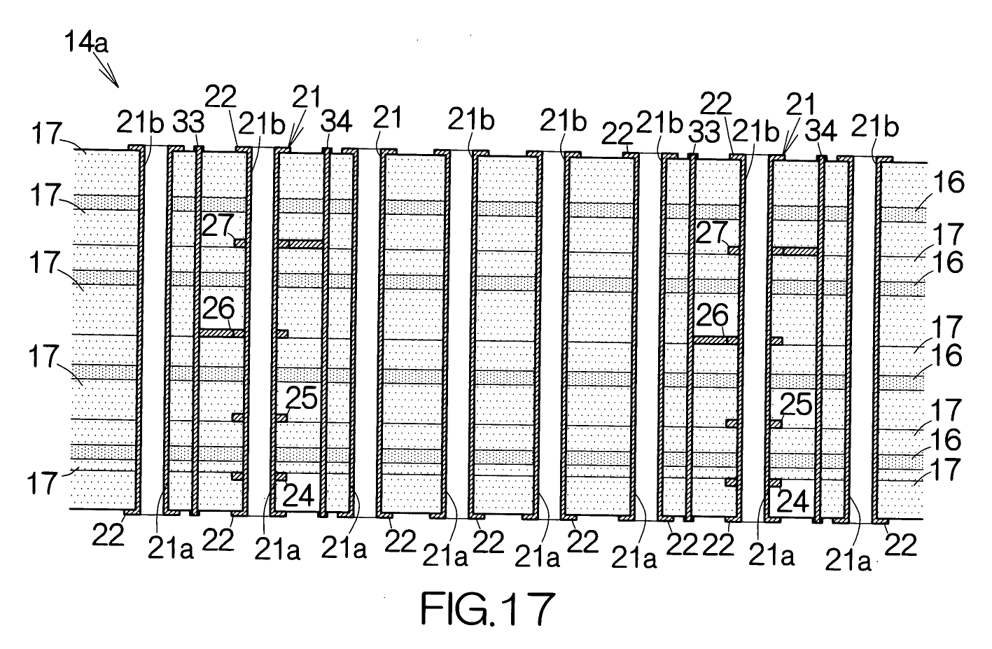

As shown in FIG. 17, a printed wiring board 14a may be utilized in place of the printed wiring board 14 in the main board unit 13. The first to fourth land patterns 24, 25, 26, 27 may be exposed in the through bore 21a of the individual plated through hole 21 in the printed wiring board 14a. The first to fourth land patterns 24, 25, 26, 27 are connected to the metallic wall 21b. Formation of the aforementioned resist materials 43 may be omitted in the plating process in a method of making the printed wiring board 14a. Like reference numerals are attached to the structure or components equivalent to those of the aforementioned printed wiring board 14.

The first contact 52 is connected to the land pattern 22 of the plated through hole 21 on the front surface of the printed wiring board 14a, for example. The second contact 53 is connected to the second electrically-conductive material 34 on the front surface of the printed wiring board 14a, for example. Electric resistance is measured between the first and second contacts 52, 53. When the measured resistance is lower than the predetermined resistance, it is detected that no cracks are formed in the metallic wall 21b between the fourth land pattern 27 and the front surface of the printed wiring board 14a.

Next, the second contact 53 is connected to the first electrically-conductive material 33 on the front surface, for example, of the printed wiring board 14a while the first contact 52 is kept connected to the land pattern 22. Electric resistance is measured between the first and second contacts 52, 53. When the measured resistance is lower than the predetermined resistance, it is detected that no cracks are formed in the metallic wall 21b between the third land pattern 26 and the front surface of the printed wiring board 14a.

When the measured resistance is equal to or higher than the predetermined resistance, it is detected that a crack or cracks are formed in the metallic wall 21b between the third land pattern 26 and the front surface of the printed wiring board 14a. Here, since it has been detected that no cracks are formed in the metallic wall 21b between the third land pattern 26 and the front surface of the printed wiring board 14a, it is detected that the crack or cracks are formed in the metallic wall 21b between the third land pattern 26 and the fourth land pattern 27. The position or positions of crack or cracks are roughly found in this manner. The third and fourth electrically-conductive materials 37, 38 are likewise utilized for such detection of a crack.

It should be noted that the first to fourth land patterns 24, 25, 26, 27 may be placed at any positions defined in the direction of the thickness of the printed wiring board 14 in the main board unit 13. The numbers of the land patterns 24, 25, 26, 27 may be changed. The first to fourth bores 31, 32, 35, 36 may not be a through bore. The first to fourth bores 31, 32, 35, 36 maybe a bottomed bore formed from the front surface to the back surface of the printed wiring board 14, for example.

What is claimed is:

1. A printed wiring board comprising:
a substrate including insulating layers;
a through bore penetrating through the substrate between a first surface and a second surface opposite the first surface, the through bore defining a space surrounded by an insulating wall surface; and
an auxiliary electrically-conductive body exposed in the space of the through bore at a position between adjacent ones of the insulating layers, the auxiliary electrically-conductive body extending to an exposed portion at the first surface.

2. The printed wiring board according to claim 1, wherein the auxiliary electrically-conductive comprises:
an electrically-conductive pattern disposed on a surface of one of the insulating layers; and
an electrically-conductive material placed in a bore extending from the first surface to the surface of the insulating layer, the electrically-conductive material extending from the first surface to the surface of the insulating layer.

3. A printed wiring board unit comprising:
a substrate including insulating layers;
a through bore penetrating through the substrate between a first surface and a second surface opposite the first surface, the through bore defining a space surrounded by an insulating wall surface;
an electronic component placed on the first surface of the substrate, the electronic component having a lead terminal placed in the through bore;
an electrically-conductive body placed in the through bore to extend to an exposed portion at least one of the first and second surfaces, the electrically-conductive body contacting with the lead terminal of the electronic component; and
an auxiliary electrically-conductive body exposed in the space of the through bore at a position between adjacent ones of the insulating layers for connection to the electrically-conductive body, the auxiliary electrically-conductive body extending to an exposed portion at least one of the first and second surfaces.

4. The printed wiring board unit according to claim 3, wherein the auxiliary electrically-conductive body comprises:
an electrically-conductive pattern placed on a surface of one of the insulating layers; and
an electrically-conductive material placed in a bore extending from at least one of the first and second surfaces to the surface of the insulating layer, the electrically-conductive material extending from the first surface to the surface of the insulating layer.

5. A method of making a printed-wiring board, comprising:
forming a substrate including insulating layers; and
forming a through bore penetrating through the substrate from a first surface of the substrate to a second surface opposite the first surface to define a space surrounded by an insulating wall surface, the through bore allowing exposure of an auxiliary electrically-conductive body in the space at a position between adjacent ones of the insulating layers, the auxiliary electrically-conductive body extending to an exposed portion at the first surface.

6. A method of detecting a rising level of an electrically-conductive body, comprising:
connecting a first contact to an electrically-conductive material placed in a through bore penetrating through a substrate including insulating layers from a first surface of the substrate to a second surface opposite the first surface, the electrically-conductive body exposed at least one of the first and second surfaces, the through bore receiving a lead terminal of an electronic component mounted on the first surface;
connecting a second contact to an auxiliary electrically-conductive body exposed in a space defined in the through bore at a position between adjacent ones of the insulating layers, the electrically-conductive body extending to an exposed portion at least one of the first and second surfaces; and
measuring electric resistance between the first and second contacts.

7. An electronic apparatus including a printed wiring board unit, the printed wiring board comprising:
a substrate including insulating layers;
a through bore penetrating through the substrate between a first surface and a second surface opposite the first surface, the through bore defining a space surrounded by an insulating wall surface;
an electronic component placed on the first surface of the substrate, the electronic component having a lead terminal placed in the through bore;
an electrically-conductive body placed in the through bore to extend to an exposed portion at least one of the first and second surfaces, the electrically-conductive body contacting with the lead terminal of the electronic component; and
an auxiliary electrically-conductive body exposed in the space of the through bore at a position between adjacent ones of the insulating layers for connection to the electrically-conductive body, the auxiliary electrically-conductive body extending to an exposed portion at least one of the first and second surfaces.

8. The electronic apparatus according to claim 7, wherein the auxiliary electrically-conductive comprises:
an electrically-conductive pattern placed on a surface of one of the insulating layers; and
an electrically-conductive material placed in a bore extending from at least one of the first and second surfaces to the surface of the insulating layer, the electrically-conductive material extending from the first surface to the surface of the insulating layer.
